(19) United States
(12) Patent Application Publication
(10) Pub. No.: US 2026/0173454 A1
(43) Pub. Date: Jun. 18, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: I-HAN HUANG, NEW TAIPEI CITY (TW); CHU-YUAN HSU, TAICHUNG CITY (TW); JIA-CHUAN YOU, TAOYUAN CITY (TW); CHIA-HAO CHANG, HSINCHU CITY (TW); KUO-CHENG CHIANG, HSINCHU COUNTY (TW)

(21) Appl. No.: 18/977,997

(22) Filed: Dec. 12, 2024

(51) Int. Cl. H10D 30/67; H10D 30/00; H10D 30/01; H10D 30/43; H10D 62/10; H10D 62/13; H10D 64/01

(52) U.S. Cl. CPC H10D 30/6739; H10D 30/014; H10D 30/0191; H10D 30/43; H10D 30/502; H10D 30/6735; H10D 30/6757; H10D 62/121; H10D 62/151; H10D 64/017

(57) ABSTRACT

A semiconductor structure includes a stack of nanostructure channels, a gate structure wrapping each of the nanostructure channels, a source/drain structure at two sides of the gate structure, and a sidewall spacer over sidewalls of the gate structure. The sidewall spacer includes an air gap sealed within a first dielectric layer. The air gap includes a first bottom and a second bottom at different levels.

### BACKGROUND

Recently, multi-gate devices have been introduced in an effort to improve gate control by increasing gate-channel coupling, reduce off-state current, and reduce short-channel effects (SCEs). One such multi-gate device that has been introduced is a fin field-effect transistor (FinFET). The FinFET includes a fin-like structure that extends from a substrate on which it is formed. The fin-like structure is used to form a FET channel. A further type of multi-gate device, introduced in part to address performance challenges associated with some configurations of FinFETs, is referred to as a gate-all-around (GAA) transistor. GAA devices get their name from a gate structure which extends completely around the channel, providing better electrostatic control than that provided by FinFETs. GAA devices and processes of fabricating thereof are compatible with complementary metal-oxide-semiconductor (CMOS) processes, and their three-dimensional structure allows them to be aggressively scaled while maintaining gate control and mitigating SCEs. However, GAA device fabrication can be challenging, and current methods continue to present challenges with respect to both device fabrication and performance. Thus, existing techniques are not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart representing a method for forming a semiconductor structure according to aspects of the present disclosure.

FIG. 2A is a perspective view of an intermediate semiconductor structure at a fabrication stage according to aspects of one or more embodiments of the present disclosure, and FIG. 2B is a cross-sectional view taken along line A1-A1′ of FIG. 2A.

FIG. 3A is a perspective view of an intermediate semiconductor structure at a fabrication stage subsequent to that of FIG. 2A according to aspects of one or more embodiments of the present disclosure, and FIG. 3B is a cross-sectional view taken along line A1-A1′ of FIG. 3A.

FIG. 4 is a perspective view of an intermediate semiconductor structure at a fabrication stage subsequent to that of FIG. 3A according to aspects of one or more embodiments of the present disclosure.

FIG. 5 is a perspective view of an intermediate semiconductor structure at a fabrication stage subsequent to that of FIG. 4 according to aspects of one or more embodiments of the present disclosure.

FIG. 6 is a perspective view of an intermediate semiconductor structure at a fabrication stage subsequent to that of FIG. 5 according to aspects of one or more embodiments of the present disclosure.

FIG. 7 is a perspective view of an intermediate semiconductor structure at a fabrication stage subsequent to that of FIG. 6 according to aspects of one or more embodiments of the present disclosure.

FIG. 8A is a perspective view of an intermediate semiconductor structure at a fabrication stage subsequent to that of FIG. 7 according to aspects of one or more embodiments of the present disclosure, and FIG. 8B is a cross-sectional view taken along line A1-A1′ of FIG. 8A.

FIG. 9A is a perspective view of an intermediate semiconductor structure at a fabrication stage subsequent to that of FIG. 8A according to aspects of one or more embodiments of the present disclosure, and FIG. 9B is a cross-sectional view taken along line A1-A1′ of FIG. 9A.

FIG. 10A is a perspective view of an intermediate semiconductor structure at a fabrication stage subsequent to that of FIG. 9A according to aspects of one or more embodiments of the present disclosure, and FIG. 10B is a cross-sectional view taken along line A1-A1′ of FIG. 10A.

FIG. 11A is a perspective view of an intermediate semiconductor structure at a fabrication stage subsequent to that of FIG. 10A according to aspects of one or more embodiments of the present disclosure, and FIG. 11B is a cross-sectional view taken along line B-B′ of FIG. 11A.

FIG. 12A is a perspective view of an intermediate semiconductor structure at a fabrication stage subsequent to that of FIG. 11A according to aspects of one or more embodiments of the present disclosure, and FIG. 12B is a cross-sectional view taken along line A1-A1′ of FIG. 12A.

FIG. 13A is a perspective view of an intermediate semiconductor structure at a fabrication stage subsequent to that of FIG. 12A according to aspects of one or more embodiments of the present disclosure, FIG. 13B is a cross-sectional view taken along line A1-A1′ of FIG. 13A, and FIG. 13C is a cross-sectional view taken along line A2-A2′ of FIG. 13A.

FIG. 14A is a cross-sectional view of an intermediate semiconductor structure at a fabrication stage subsequent to that of FIG. 11A according to aspects of one or more embodiments of the present disclosure, and FIG. 14B is a cross-sectional view at a fabrication stage subsequent to that of FIG. 13B according to aspects of one or more embodiments of the present disclosure.

FIGS. 15A and 15B are cross-sectional views of a semiconductor structure according to aspects of one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; the scope of the disclosure being defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the

### Gaa Structure.

The term “nano-structure” refers to atomic, molecular or macromolecular particles typically having a thickness in a range of approximately 1 to 100 nanometers and a width greater than the thickness. For example, the width may be at least twice the thickness, but the disclosure is not limited thereto. Typically, the novel and differentiating properties and functions of nanosheet components are observed or developed at a critical length scale of under 100 nm. In some embodiments, “nano-structure” components can also be referred to as “nano-wire,” “nano-sheet,” “nano-slab,” “nano-ring” or “multi-bridge channel” components.

Reducing effective capacitance (C_{eff}) in multi-gate transistor devices (i.e., GAA transistor devices) is important for improving performance, reducing power consumption, and minimizing signal delay in integrated circuits, especially as transistor dimensions continue to shrink and semiconductor technology progresses to smaller geometries.

The present disclosure therefore provides a semiconductor structure and a method for forming the same. In some embodiments, air spacers are formed on sidewalls of a gate structure of a multi-gate transistor device. The air spacers help to reduce effective capacitance by about 3% to 20%. In some embodiments, uniformity of contact structures, which are formed to provide electrical connection between the multi-gate transistor device and a back-end-of-line (BEOL) interconnect, is improved by the method for forming the semiconductor structure provided by the present disclosure.

The embodiments described herein may be employed in design and/or fabrication of any type of integrated circuit, or portion thereof, which may include any of a plurality of various devices and/or components such as a static random-access memory (SRAM) and/or other logic circuits, passive components such as resistors, capacitors, and inductors, and active components such as P-channel field-effect transistors (PFETs), N-channel FETs (NFETs), metal-oxide-semiconductor field-effect transistors (MOSFETs), complementary metal-oxide-semiconductor (CMOS) transistors, bipolar transistors, high voltage transistors, high frequency transistors, Omega-gate (Ω-gate) devices, or Pi-gate (H-gate) devices, as well as strained-semiconductor devices, silicon-on-insulator (SOI) devices, partially-depleted SOI (PD-SOI) devices, fully-depleted SOI (FD-SOI) devices, other memory cells, or other devices known in the art. One of ordinary skill may recognize other embodiments of semiconductor devices and/or circuits, including the design and fabrication thereof, which may benefit from aspects of the present disclosure.

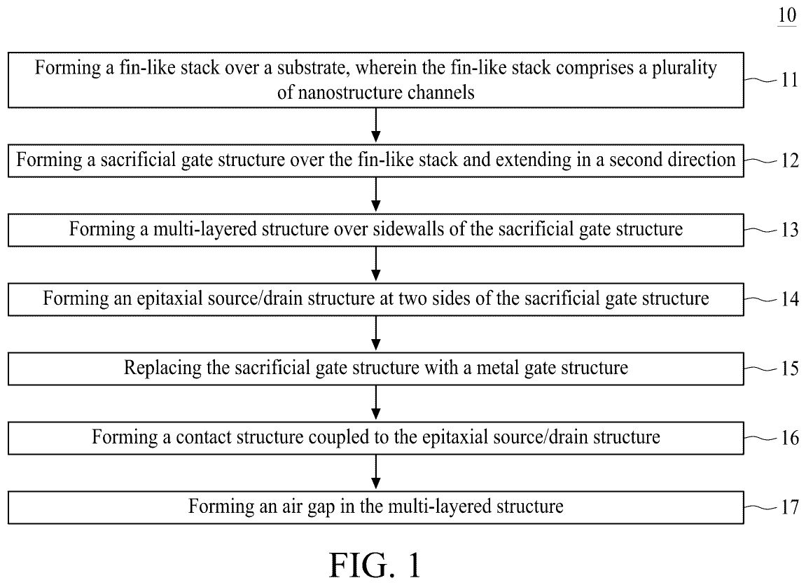

FIG. 1 is a flowchart representing a method for forming a semiconductor structure 10 according to aspects of the present disclosure. The method 10 includes a number of operations (11, 12, 13, 14, 15, 16 and 17). The method 10 will be further described according to one or more embodiments. It should be noted that the operations of the method 10 may be rearranged or otherwise modified within the scope of the various aspects. It should be further noted that additional processes may be provided before, during, and after the method 10, and that some other processes may be briefly described herein. Thus, other implementations are possible within the scope of the various aspects described herein.

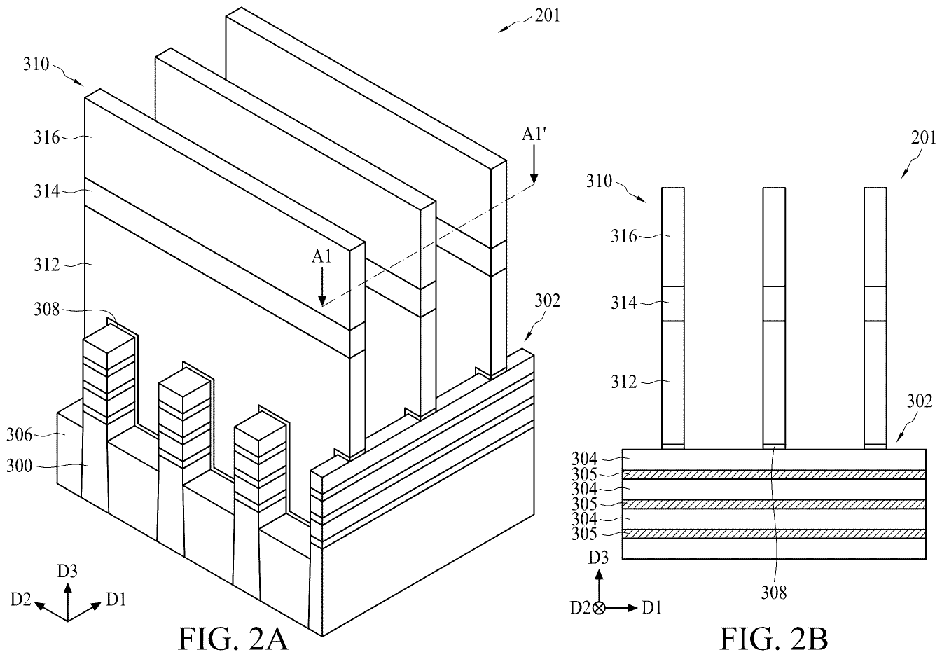

Please refer to FIGS. 2A and 2B, wherein FIG. 2A is a perspective view illustrating an intermediate semiconductor structure at a fabrication stage constructed according to aspects of one or more embodiments of the present disclosure, and FIG. 2B is a cross-sectional view taken along line A1-A1′ of FIG. 2A. In some embodiments, FIGS. 2A and 2B illustrate an intermediate semiconductor structure 201 according to some embodiments corresponding to operation 11 and operation 12. In operation 11, a fin-like stack 302 is formed over a substrate 300. In some embodiments, the substrate 300 may be made of elemental semiconductor materials such as crystalline silicon (Si), diamond or germanium (Ge); compound semiconductor materials such as silicon carbide (SiC), gallium arsenic (GaAs), indium arsenide (InAs), or indium phosphide (InP); or alloy semiconductor materials such as silicon germanium (SiGe), silicon germanium carbide (SiGeC), gallium arsenic phosphide (GaAsP), or gallium indium phosphide (GaInP). The substrate 300 may include various layers, including conductive or insulating layers formed on a semiconductor substrate. The substrate 300 may be a bulk silicon substrate, a silicon-on-insulator (SOI) substrate, or a germanium-on-insulator (GOI) substrate. The substrate 300 may also include various doping configurations depending on design requirements, such as different doping profiles for different device types. For example, different doping profiles (e.g., n wells or p wells) may be formed on the substrate 300 designed for different device types (e.g., n-type field-effect transistors (NFET), or p-type field-effect transistors (PFET)). The suitable doping may include ion implantation of dopants and/or diffusion processes. Additionally, the substrate 300 may be doped with p-type impurities or n-type impurities, or may be undoped.

In some embodiments, a plurality of alternating semiconductor layers 304 and 305 are formed over the substrate 300. The alternating semiconductor layers 304 and 305 may be used to selectively process some of the layers. Accordingly, compositions of the semiconductor layers 304 and 305 may have different oxidation rates, etchant sensitivity, and/or other differing properties. The semiconductor layers 304 and 305 may have thicknesses chosen based on device performance considerations. In some embodiments, the semiconductor layers 304 are substantially uniform in thickness, and the semiconductor layers 305 are substantially uniform in thickness.

In some embodiments, either of the semiconductor layers 304 and 305 may include Si. In some embodiments, either of the semiconductor layers 304 and 305 may include other materials such as Ge, a compound semiconductor such as silicon carbide (SiC), gallium arsenide (GaAs), gallium phosphide (GaP), indium phosphide (InP), indium arsenide (InAs), and/or indium antimonide (InSb), an alloy semiconductor such as SiGe, GaAsP, AlInAs, AlGaAs, InGaAs, GaInP, and/or GaInAsP, or a combination thereof. In some embodiments, the semiconductor layers 304 and 305 may be undoped or substantially dopant-free, where, for example, no doping is performed during the forming of the semiconductor layers 304 and 305. Alternatively, the semiconductor layers 304 and 305 may be doped. In some embodiments, the semiconductor layers 304 or 305 serves as nanostructure channels for a multi-gate transistor device (i.e., a GAA transistor device). In such embodiments, the semiconductor layers 304 or 305 may be doped with a p-type dopant such as boron (B), aluminum (Al), In, or Ga for forming a p-type channel, or an n-type dopant such as P, As, or Sb for forming an n-type channel. In some embodiments, the semiconductor layers 304 and 305 are formed by epitaxial growth processes. For example, the semiconductor layers 304 and 305 may be formed using a molecular beam epitaxy (MBE) process, a metalorganic chemical vapor deposition (MOCVD) process, and/or another suitable epitaxial growth processes. It should be noted that while the epitaxial layers 304 and 305 are shown as having a particular stacking sequence, where an epitaxial layer 304 is the topmost layer, other configurations are possible.

Still referring to FIGS. 2A and 2B, the fin-like stack 302 may be fabricated using suitable operations including photolithography and etch operations. In some embodiments, forming the fin-like stack 302 may further include a trim process to decrease a width and/or a height of the fin-like stack 302. The trim process may include wet or dry etching processes. The height and the width of the fin-like stack 302 may be chosen based on device performance considerations. Further, the fin-like stack 302 can extend along a first direction D1 as shown in FIGS. 2A and 2B. Additionally, the fin-like stack 302 can be arranged in a second direction D2, wherein the second direction D2 is different from the first direction D1.

Still referring to FIGS. 2A and 2B, in some embodiments, gaps between the fin-like stacks 302 are filled with a dielectric material for forming shallow trench isolations (STIs) 306 interposing the fin-like stacks 302. In some embodiments, the STIs 306 are recessed, thereby exposing portions of sidewalls of the fin-like stacks 302. In some embodiments, the dielectric material used to fill the gaps and to form the STIs 306 may include silicon oxide (SiO), silicon nitride (SiN), silicon oxynitride (SiON), fluorine-doped silicate glass (FSG), a low-k dielectric, combinations thereof, and/or other suitable materials known in the art.

In some embodiments, a cap layer or a liner 308 is conformally formed over the fin-like stacks 302. Accordingly, tops and the sidewalls that are exposed through the STIs 306 are covered by the cap layer 308. In some embodiments, the cap layer 308 includes dielectric materials such as SiN, SiON, silicon carbonitride (SiCN), silicon oxycarbonitride (SiOCN), or other appropriate material. In other embodiments, the cap layer 308 may include silicon germanium (SiGe).

In some embodiments, in operation 12, a sacrificial gate structure 310 is formed over the fin-like stack 302 and the substrate 300. In some embodiments, a polysilicon layer 312 is formed over the substrate 300 and the fin-like stack 302. A patterned hard mask is formed over the polysilicon layer 312. In some embodiments, the patterned hard mask may be a patterned multiple hard mask. For example, the patterned multiple hard mask may include a first layer 314 and a second layer 316, but the disclosure is not limited thereto. In some embodiments, the first layer 314 and the second layer 316 may include different dielectric materials. The polysilicon layer 312 is patterned through the patterned hard mask 314/316, thereby forming the sacrificial gate structure 310. The sacrificial gate structure 310 may be replaced at a later processing stage by a metal gate electrode (MG) as discussed below. As shown in FIGS. 2A and 2B, the sacrificial gate structure 310 extends along the second direction D2. Additionally, the sacrificial gate structures 310 may be arranged along the first direction D1. Each of the sacrificial gate structures 310 is at least partially disposed over the fin-like stack 302. Additionally, the fin-like stack 302 protrudes in a third direction D3 from the substrate 300, wherein the third direction D3 is perpendicular to both the first direction D1 and the second direction D2.

In some embodiments, portions of the cap layer 308 that are exposed through the sacrificial gate structures 310 may be removed, thereby exposing the semiconductor layers 304 and 305, as shown in FIG. 2A.

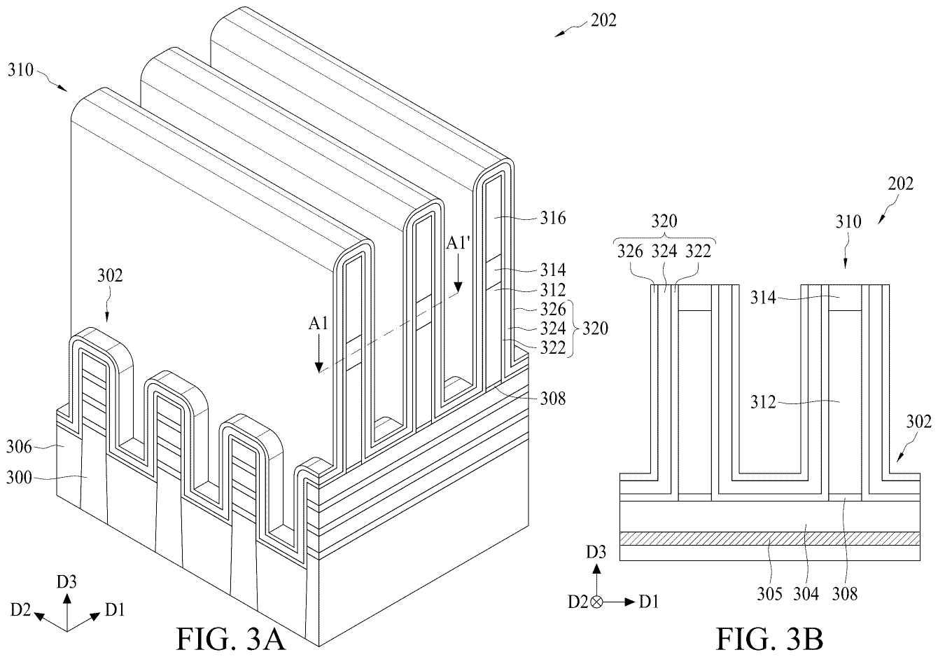

Please refer to FIGS. 3A and 3B, wherein FIG. 3A is a perspective view of an intermediate semiconductor structure 202, and FIG. 3B is a cross-sectional view taken along line A1-A1′ of FIG. 3A. In some embodiments, in operation 13, a dielectric structure 320 is formed. In some embodiments, the dielectric structure 320 may be a multi-layered structure 320 that is formed over sidewalls of the sacrificial gate structures 310. The multi-layered structure 320 may be a tri-layered structure. In some embodiments, the multi-layered structure 320 includes a first dielectric layer 322, a second dielectric layer 326, and a sacrificial layer 324 disposed between the first dielectric layer 322 and the second dielectric layer 326. The first dielectric layer 322 may include silicon oxycarbonitride (SiOCN), silicon carbonitride (SiCN), or silicon oxycarbide (SiOC), but the disclosure is not limited thereto. The second dielectric layer 326 may include SiOCN, SiCN, or SiOC, but the disclosure is not limited thereto. In some embodiments, the first and second dielectric layers 322 and 326 include a same material. In some alternative embodiments, the first and second dielectric layers 322 and 326 include different materials. In some embodiments, a thickness of each of the first and second dielectric layers 322 and 326 may be less than approximately 6 nanometers, but the disclosure is not limited thereto. In embodiments, the thickness of the first dielectric layer 322 and the thickness of the second dielectric layer 326 may be same, but the disclosure is not limited thereto. The sacrificial layer 324 includes a material different from materials of the first and second dielectric layers 322 and 326. In some embodiments, the sacrificial layer 324 may include silicon, but the disclosure is not limited thereto. In some embodiments, a thickness of the sacrificial layer 324 is greater than the thickness of the first dielectric layer 322, and greater than the thickness of the second dielectric layer 326. For example but not limited thereto, the thickness of the sacrificial layer 324 may be between approximately 2 nanometers and 8 nanometers.

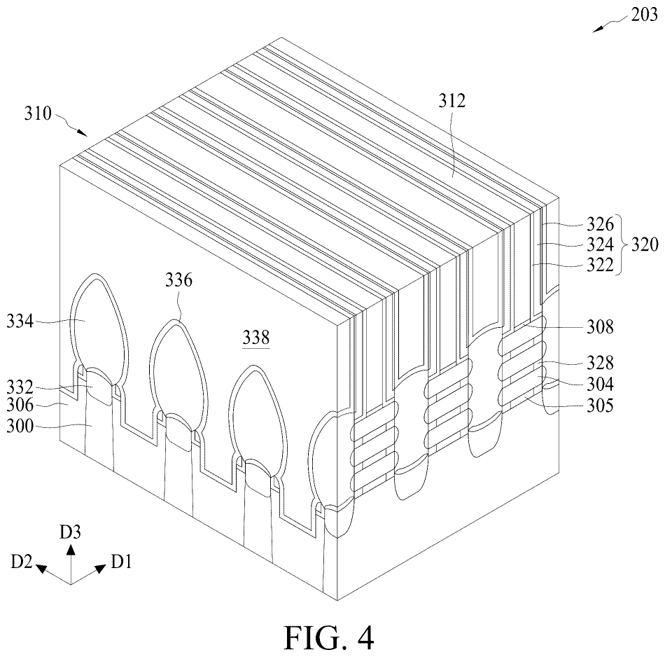

Referring to FIG. 4, which is a perspective view of an intermediate semiconductor structure 203, in some embodiments, an etch-back operation is performed, such that portions of the first dielectric layer 322, portions of the sacrificial layer 324, and portions of the second dielectric layer 326 are removed. Accordingly, the multi-layered structure 320 remains over the sidewalls of the sacrificial gate structure 310. In some embodiments, the remaining multi-layered structure 320 may be referred to as a sidewall spacer structure. In some embodiments, after the forming the sidewall spacer structure, portions of the semiconductor layers 304 and 305 are exposed.

Still referring to FIG. 4, in some embodiments, the exposed semiconductor layers 305 of the fin-like stack 302 are partially removed, and thus a plurality of notches (not shown) are formed between the remaining semiconductor layers 304. Subsequently, an insulating layer is formed to fill the notches. In some embodiments, the insulating layer may include SiOCN, SiCN, or SiOC, but the disclosure is not limited thereto. Subsequently, portions of the insulating layer may be removed, thereby forming inner spacers 328. In some embodiments, a thickness of the inner spacer 328 may be between approximately 2 nanometers and approximately 8 nanometers, but the disclosure is not limited thereto.

Still referring to FIG. 4, in some embodiments, in operation 14, epitaxial source/drain structures 330 are formed at two sides of the sacrificial gate structure 310. The epitaxial source/drain structures 330 may be a source or a drain, individually or collectively depending upon the context. In some embodiments, top surfaces of the epitaxial source/drain structures 330 can be relatively higher than a top surface of the fin-like stack 302. In some embodiments, the epitaxial source/drain structures 330 are formed by forming recesses in the fin-like stacks 302 and growing a strained material in the recesses by an epitaxial (epi) process. In addition, a lattice constant of the strained material may be different from a lattice constant of the substrate 300. Accordingly, the epitaxial source/drain structures 330 serve as stressors that improve carrier mobility. In some embodiments, the epitaxial source/drain structure 330 may include a first epitaxial layer 332 and a second epitaxial layer 334. In some embodiments, the first epitaxial layer 332 may include non-doped semiconductor material such as Si, SiGe, or silicon boride (SiB). A thickness of the first epitaxial layer 332 may be between approximately 5 nanometers and approximately 45 nanometers, but the disclosure is not limited thereto. When the epitaxial source/drain structure 330 is formed for an n-FET, the second epitaxial layer 334 may be a semiconductor epitaxial layer doped with an n-type impurity, for example, but not limited to phosphorus. The second epitaxial layer 334 may include silicon phosphorous (SiP), silicon arsenide (SiAs), silicon germanium arsenide (SiGeAs), or combinations thereof. Other suitable materials for the second epitaxial layer 334 are within the contemplated scope of the present disclosure. When the epitaxial source/drain structure 330 is formed for a p-FET, the second epitaxial layer 334 may be a semiconductor epitaxial layer doped with a p-type impurity. The second epitaxial layer 334 may be a boron-doped (B-doped) epitaxial layer, for example but not limited thereto. The second epitaxial layer 334 may include a SiGe/Si stack, SiB, or a combination thereof. Other suitable materials for the second epitaxial layer 334 are within the contemplated scope of the present disclosure.

Still referring to FIG. 4, in some embodiments, after the forming of the epitaxial source/drain structures 330, a bottom contact etch-stop layer (BCESL) 336 can be formed to cover the sacrificial gate structures 310 over the substrate 300. In some embodiments, the BCESL 336 can include silicon nitride (SiN), SiCN, SiOCN, SiOC, and/or other applicable materials. In some embodiments, a thickness of the BCESL 336 may be between approximately 2 nanometers and approximately 8 nanometers, but the disclosure is not limited thereto. Subsequently, an inter-layer dielectric (ILD) layer 338 can be formed on the BCESL 336 over the substrate 300 in accordance with some embodiments. The ILD layer 338 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), and polyimide.

Next, a polishing process is performed on the ILD layer 338, the BCESL 336, the multi-layered structure 320, and the patterned hard mask 314/316 to expose top surfaces of the polysilicon layer 312 of the sacrificial gate structures 310. In some embodiments, the ILD layer 338, the BCESL 336, the multi-layered structure 320 and the patterned hard mask 314/316 are planarized by a chemical mechanical polishing (CMP) process until the top surfaces of the polysilicon layer 312 are exposed, as shown in FIG. 4. In some embodiments, the ILD layer 338 may laterally surrounds the source/drain structure 330.

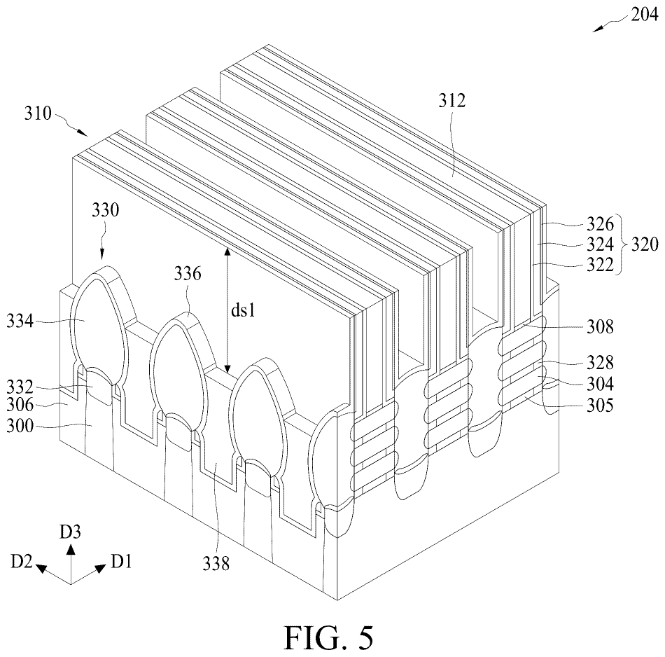

Referring to FIG. 5, which is a perspective view of an intermediate semiconductor structure 204, in some embodiments, the ILD layer 338 may be recessed after the CMP process. In such embodiments, a top surface of the ILD layer 338 is lower than top surfaces of the epitaxial source/drain structures 330. In such embodiments, the BCESL 336 helps to protect the epitaxial source/drain structures 330 during the recessing of the ILD layer 338. In some embodiments, a distance ds1 between the top surface of the sacrificial gate structure 310 and a top surface of the recessed ILD layer 338 is between approximately 30 nanometers and approximately 60 nanometers, but the disclosure is not limited thereto.

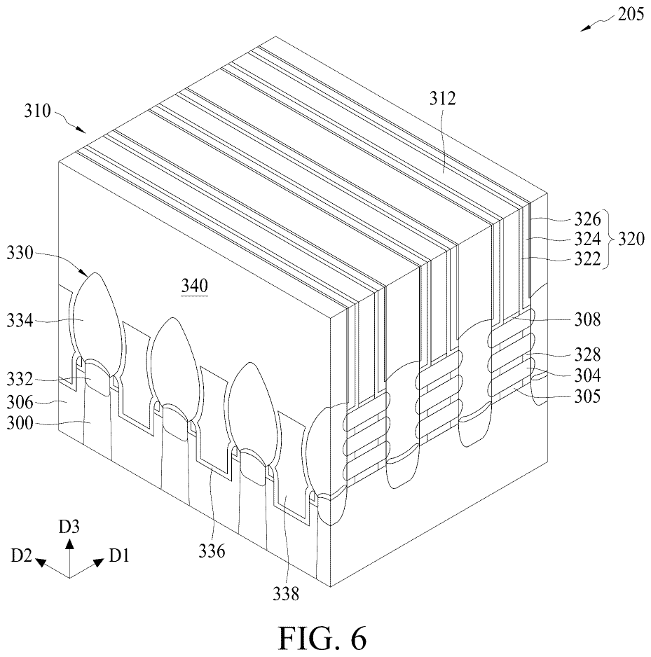

Referring to FIG. 6, which is a perspective view of an intermediate semiconductor structure 205, in some embodiments, a dielectric layer 340 is formed over the substrate 300, and a planarization operation is then performed. Accordingly, a top surface of the dielectric layer 340 may be aligned with (i.e., coplanar with) the top surface of the sacrificial gate structure 310, as shown in FIG. 6. The dielectric layer 340 includes a material different from that of the ILD layer 338. In some embodiments, the dielectric layer 340 may include silicon nitride, but the disclosure is not limited thereto. In some embodiment, a dielectric constant of the dielectric layer 340 is greater than a dielectric constant of the ILD layer 338. In some embodiments, the BCESL layer 336, the ILD layer 338 and the dielectric layer 340 may be referred to as a first dielectric structure.

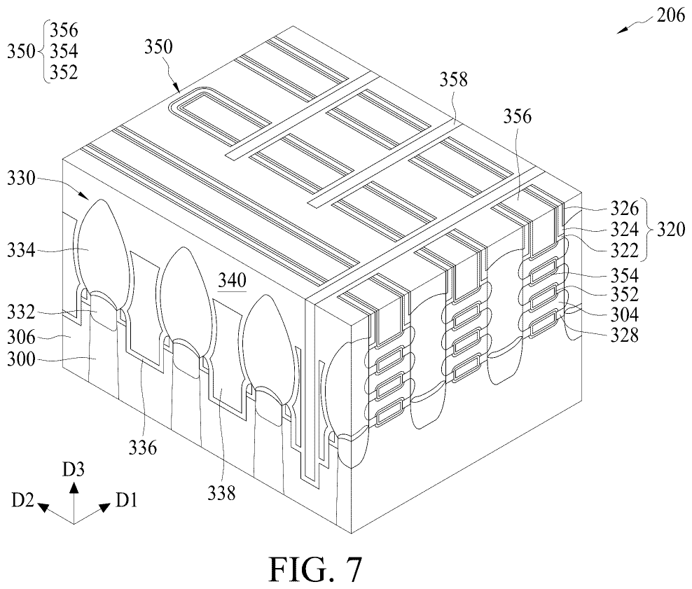

Please refer to FIG. 7, which is a perspective view of an intermediate semiconductor structure 206. In some embodiments, in operation 15, the sacrificial gate structure 310 is replaced with a metal gate structure 350. In some embodiments, operation 15 includes further operations. For example, in some embodiments, the polysilicon layer 312 of the sacrificial gate structure 310 is removed to form a gate trench (not shown) over the substrate 300. Thereafter, portions of the fin-like stack 302 are removed. In some embodiments, the semiconductor layers 305 are removed such that the semiconductor layers 304 remain and are separate from each other in the gate trench. The semiconductor layers 304 serve as nanostructure channels 304 of the GAA transistor device. In some embodiments, each of the nanostructure channels 304 is trimmed to have a desired shape and desired dimensions (i.e., thickness and width). By adjusting the width and the thickness of the nanostructure channels 304, a threshold voltage (Vt) of a FET device to be formed can be adjusted to meet requirements.

Still referring to FIG. 7, in some embodiments, an interfacial layer (IL) 352 may be formed over each of the nanostructure channels 304. In such embodiments, a thickness of the IL 352 may be between approximately 0.5 nanometers and approximately 2 nanometers, but the disclosure is not limited thereto. Subsequently, a high-k gate dielectric layer 354 is formed over the IL 352 to surround each of the nanostructure channels 304. In some embodiments, a thickness of the high-k gate dielectric layer 354 may be between approximately 1 nanometer and approximately 3 nanometers, but the disclosure is not limited thereto. In some embodiments, the high-k gate dielectric layer 354 includes a high-k dielectric material having a high dielectric constant, for example, a dielectric constant greater than that of thermal silicon oxide (˜3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOₓN_{y}), other suitable metal-oxides, or combinations thereof.

In some embodiments, a multiple metal layer 356 is formed over the high-k gate dielectric layer 354 to surround each of the nanostructure channels 304. In some embodiments, the multiple metal layer 356 includes at least a work function metal layer and a gap-filling layer. The work function metal layer may include one or more metal layers. The work function metal layer may be a p-type or an n-type work function layer depending on the type (PFET or NFET) of the device. The p-type work function layer comprises a metal with a sufficiently large effective work function, selected from but not restricted to the group of titanium nitride (TiN), tantalum nitride (TaN), ruthenium (Ru), molybdenum (Mo), tungsten (W), platinum (Pt), and combinations thereof. The n-type work function layer comprises a metal with sufficiently low effective work function, selected from but not restricted to the group of titanium (Ti), aluminum (Al), tantalum carbide (TaC), tantalum carbide nitride (TaCN), tantalum silicon nitride (TaSiN), titanium silicon nitride (TiSiN), and combinations thereof. The gap-filling metal layer may include Al, W, cobalt (Co), and/or other suitable materials.

Still referring to FIG. 7, in some embodiments, isolation structures 358 may be formed to interrupt a continuity of the metal gate structure 350. The isolation structures 358 may be formed by a cut metal gate (CMG) process. The term “cut metal gate process” refers to a fabrication process in which, after the replacing the sacrificial gate structure 310 with the metal gate structure 350, the metal gate structure 350 is cut to separate the metal gate structure 350 into two or more portions by the isolation structures 358. Each portion functions as a metal gate structure for an individual transistor. In some embodiments, the isolation structures 358 include SiN, SiN/SiO, SiCN, SiOC, or SiOCN, but the disclosure is not limited thereto. In some embodiments, a width of the isolation structure 358 measured in the second direction D2 may be between approximately 10 nanometers and approximately 35 nanometers, but the disclosure is not limited thereto. In some embodiments, a depth of the isolation structure 358 measured in the third direction D3 is between approximately 110 nanometers and approximately 170 nanometers, but the disclosure is not limited thereto. In some embodiments, the isolation structure 358 has more than one layer. For example, in some embodiments, the isolation structure 358 has two layers.

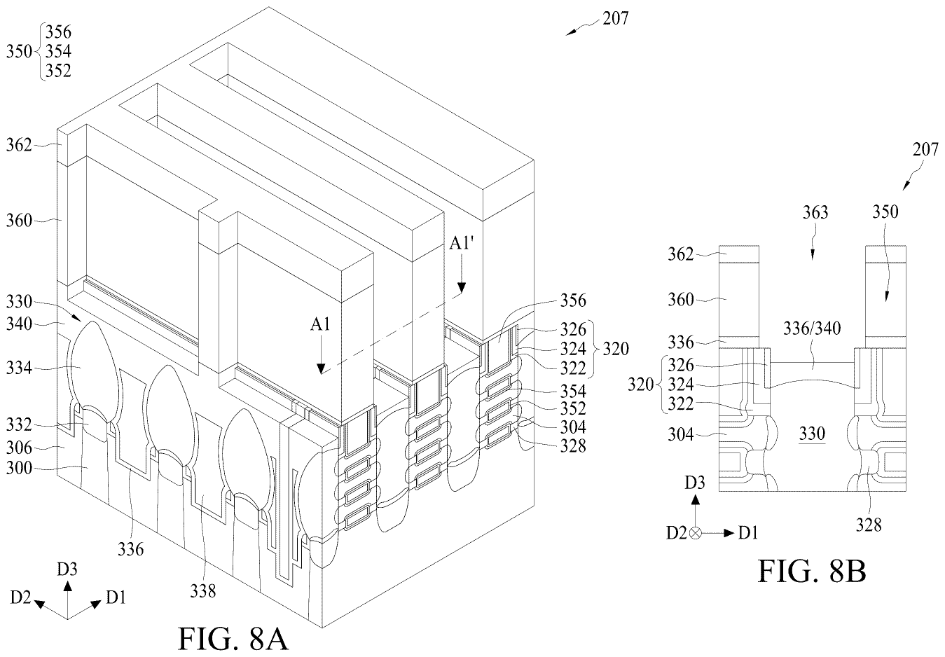

Please refer to FIGS. 8A and 8B, wherein FIG. 8A is a perspective view of an intermediate semiconductor structure 207, and FIG. 8B is a cross-sectional view taken along line A1-A1′ of FIG. 8A. In some embodiments, another dielectric layer 360 is formed over the substrate 300. The dielectric layer 360 includes a material different from that of the dielectric layer 340. For example but not limited thereto, the dielectric layer 360 includes silicon oxide. In some embodiments, the dielectric layer 360 may be referred to as a second dielectric structure over the substrate 300. In some embodiments, a patterned mask layer 362 is formed over the dielectric layer 360. Further, the dielectric layer 360 is etched through the patterned mask layer 362. Consequently, an opening 363 is formed in the dielectric layer 360. In some embodiments, a portion of the dielectric layer 340 or a portion of the BCESL 336 is exposed through the opening 363, as shown in FIGS. 8A and 8B.

Still referring to FIGS. 8A and 8B, the multi-layered sidewall spacer structure 320 is exposed through the opening 363. In some embodiments, at least the second dielectric layer 326 and the sacrificial layer 324 of the multi-layered sidewall spacer structure 320 are exposed through the opening 363.

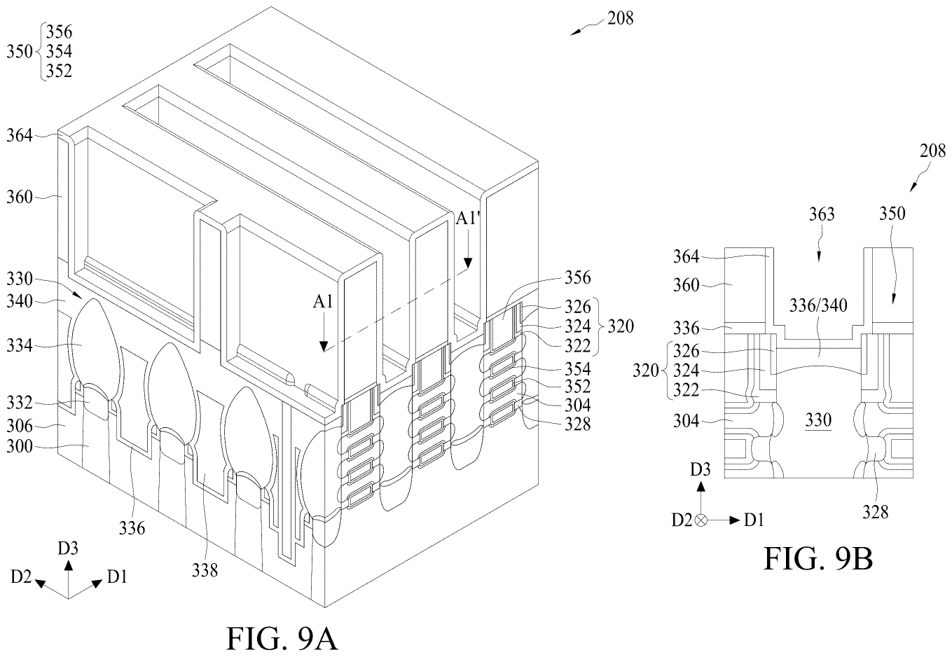

Please refer to FIGS. 9A and 9B, wherein FIG. 9A is a perspective view of an intermediate semiconductor structure 208, and FIG. 9B is a cross-sectional view taken along line A1-A1′ of FIG. 9A. In some embodiments, a dielectric layer, such as a silicon nitride re-deposition (SNR) layer 364 is conformally formed in the opening 363. In some embodiments, the SNR layer 364 covers a bottom and sidewalls of the opening 363. Further, the portion of the multi-layered structure 320 exposed through the opening 363 is covered by the SNR layer 364.

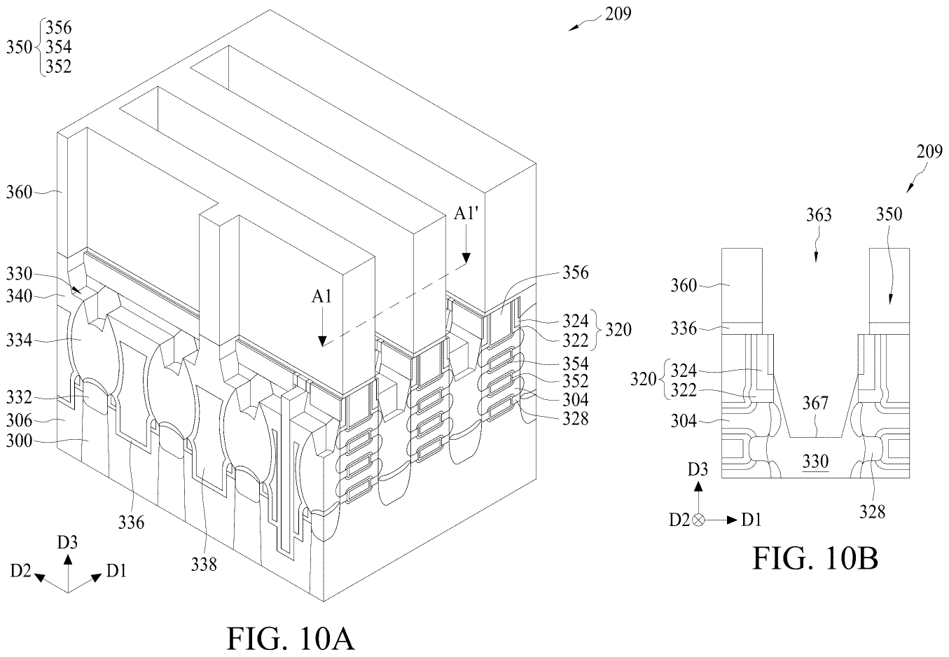

Please refer to FIGS. 10A and 10B, wherein FIG. 10A is a perspective view of an intermediate semiconductor structure 209, and FIG. 10B is a cross-sectional view taken along line A1-A1′ of FIG. 10A. In some embodiments, in operation 16, a contact structure is formed to couple to the epitaxial source/drain structure 330. In some embodiments, operation 16 includes further operations. For example, the portions of the SNR layer 364 are removed, then portions of the dielectric layer 340 are removed, and then portions of the BCESL 336 over the epitaxial source/drain structure 330 are removed. Accordingly, a portion of the epitaxial source/drain structure 330 is exposed through the opening 363.

Still referring to FIGS. 10A and 10B, in some embodiments, portions of the epitaxial source/drain structure 330 exposed through the opening 363 are removed. In such embodiments, a depth of the opening 363 is increased. Further, two bottoms of the opening 363 are created. In some embodiments, the opening 363 may have a first bottom 365 and a second bottom 367, as shown in FIG. 10A. The first bottom 365 and the second bottom 367 are at different levels. In some embodiments, the first bottom 365 is higher than the second bottom 367. In some embodiments, the dielectric layer 340 is exposed through the first bottom 365, while the epitaxial source/drain structure 330 is exposed through the second bottom 367. Additionally, in some embodiments, the second dielectric layer 326 may be removed during the removing of the portion of the SNR layer 364, the removing of the dielectric layer 340, and/or the removing of the BCESL 336. In such embodiments, the sacrificial layer 324 may be exposed through the opening 363. In some alternative embodiments, the second dielectric layer 326 remains and is exposed through the opening 363, as shown in FIGS. 10A and 10B.

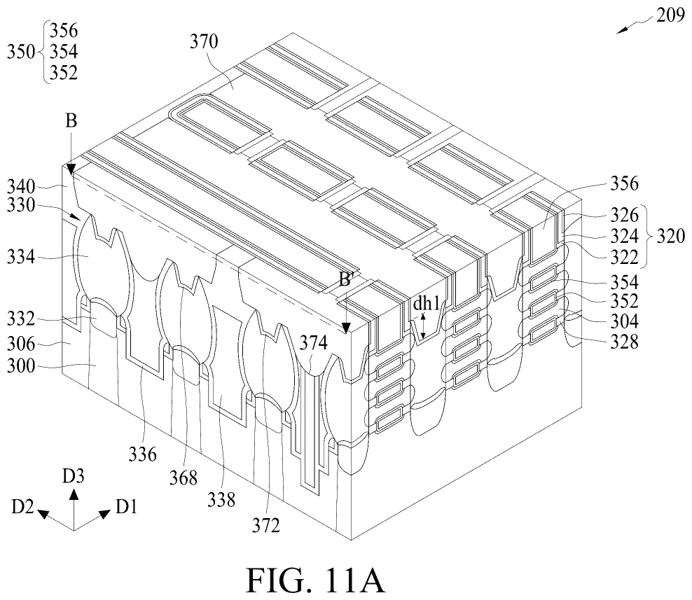

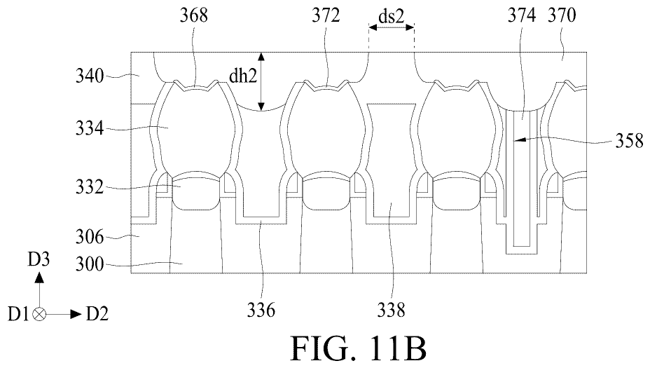

Please refer to FIGS. 11A and 11B, wherein FIG. 11A is a perspective view of an intermediate semiconductor structure 210 according to some embodiments of the present disclosure, and FIG. 11B is a cross-sectional view taken along line B-B′ of FIG. 11A. In some embodiments, a metal silicide structure 368 is formed over the second bottom 367 of the opening 363. In some embodiments, the metal silicide structure 368 includes titanium silicide (TiSi), zirconium (Zr) dipole, molybdenum silicide (MoSi) or ruthenium silicide (RuSi), but the disclosure is not limited thereto. In some embodiments, a thickness of the metal silicide structure 368 may be between approximately 1 nanometer and approximately 7 nanometers, but the disclosure is not limited thereto.

Still referring to FIGS. 11A and 11B, a contact structure 370 is formed in the opening 363. In some embodiments, a metal layer (not shown) is disposed over the substrate 300 to fill the opening 363, and an excess portion of the metal layer is then removed using, for example, but not limited to, CMP, to expose the dielectric layer 340 and to form the contact structure 370. In some embodiments, the contact structure 370 includes tungsten (W), ruthenium (Ru), Mo, cobalt (Co), or a combination thereof. Other suitable materials for the contact structure 370 are within the contemplated scope of the present disclosure. Referring to FIG. 11B, in some embodiments, a distance ds2 between adjacent contact structures 370 may be between approximately 8 nanometers and approximately 16 nanometers, but the disclosure is not limited thereto. In some embodiments, the contact structure 370 includes a first bottom 372 and a second bottom 374. The first bottom 372 is in contact with the metal silicide structure 368, while the second bottom 374 is in contact with the dielectric layer 338 and/or the isolation structure 358. The contact structure 370 is electrically connected to the epitaxial source/drain structure 330 through the metal silicide structure 368, wherein the metal silicide structure 368 helps to reduce a contact resistance. Further, sidewalls of the contact structure 370 are free of the SNR layer 364. In some embodiments, a depth dh1 measured from a top surface of the epitaxial source/drain structure 330 to the first bottom 372, is between approximately 0 nanometers and approximately 45 nanometers, as shown in FIG. 11A, but the disclosure is not limited thereto. In some embodiments, a depth dh2 measured from a top surface of the contact structure 370 to the second bottom 374, as shown in FIG. 11B, is between approximately 15 nanometers and approximately 65 nanometers, but the disclosure is not limited thereto. In some embodiments, the depth dh2 is between the top surface of the contact structure 370 and the second bottom 374 is greater than the distance dh1 between the top surface of the epitaxial source/drain structure 330 and the first bottom 372.

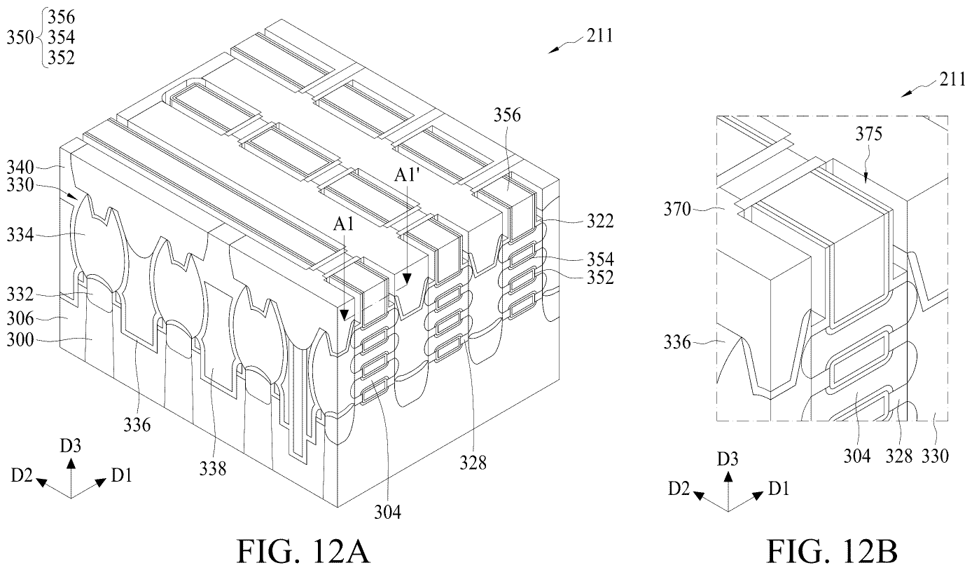

Please refer to FIGS. 12A and 12B, wherein FIG. 12A is a perspective view of an intermediate semiconductor structure 211 according to some embodiments of the present disclosure, and FIG. 12B is a cross-sectional view taken along line A1-A1′ of FIG. 12A. In some embodiments, in operation 17, an air gap is formed in the multi-layered structure 320. In some embodiments, operation 17 includes further operations. For example, the sacrificial layer 324 is removed to form a recess 375 over the substrate 300. In some embodiments, the first dielectric layer 322 may remain over sidewalls of the metal gate structure 350 and thus serves as a sidewall and a bottom of the recess 375. In such embodiments, a thickness of a portion of the first dielectric layer 322 remaining on the sidewalls of the metal gate structure is greater than 0 nanometers and less than approximately 4 nanometers, but the disclosure is not limited thereto. In other embodiments, the first dielectric layer 322 may be removed. Further, in such embodiments, the thickness of the portion of the first dielectric layer 322 remaining on the bottom of the recess 375 is greater than 0 nanometers and less than approximately 6 nanometers, but the disclosure is not limited thereto.

In some embodiments, the second dielectric layer 322 may include a material same as that of the sacrificial layer 324, such that the second dielectric layer 322 may be removed together with the removal of the sacrificial layer 324.

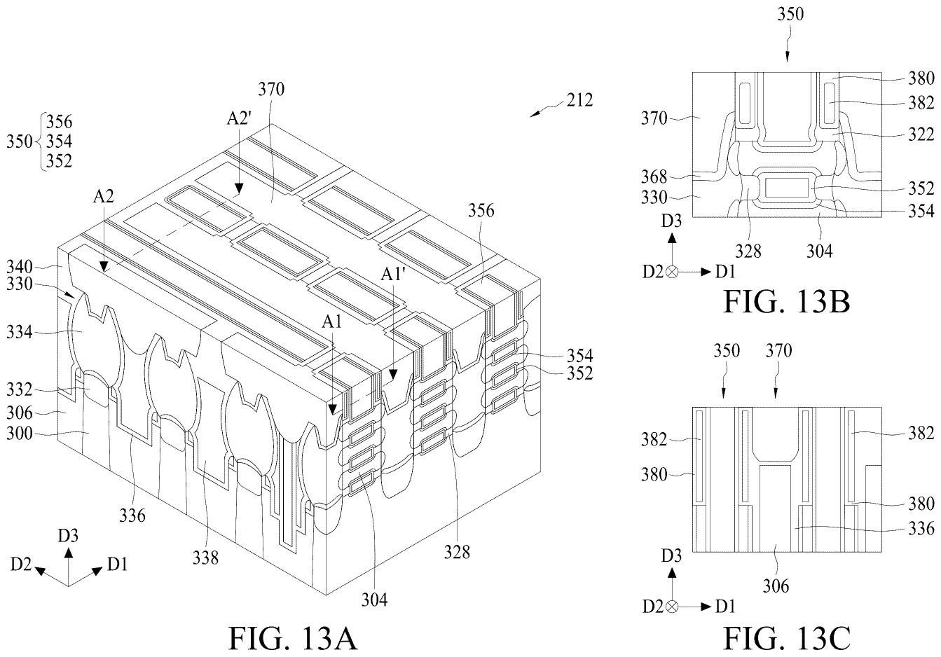

Referring to FIGS. 13A to 13C, wherein FIG. 13A is a schematic view of an intermediate semiconductor structure 212 according to some embodiments of the present disclosure, FIG. 13B is a cross-sectional view taken along line A1-A1′ of FIG. 13A, and FIG. 13C is a cross-sectional view taken along line A2-A2′ of FIG. 13A. In some embodiments, a seal layer 380 is formed over the substrate 300. The seal layer 380 includes a dielectric material such as, for example but not limited thereto, SiN. The seal layer 380 is formed to cover sidewalls and a bottom of the recess 375. Further, the seal layer 380 seals the recess 375 and thus an air gap 382 is formed within the seal layer 380. In some embodiments, the seal layer 380 is formed by a deposition. Further, a deposition rate in the third direction D3 is greater than deposition rates in the first and second directions D2 and D2. Accordingly, a thickness of the seal layer 380 along sidewalls of the air gap 382 is less than a thickness of the seal layer 380 along a bottom of the air gap 382. In some embodiments, the thickness of the seal layer 382 over the sidewalls of the air gap 382 is between approximately 0.5 nanometers and approximately 2 nanometers, and the thickness of the seal layer 382 under the bottom of the air gap 382 is between approximately 0.5 nanometers and approximately 2.5 nanometers, but the disclosure is not limited thereto. In some embodiments, the seal layer 382 may include an inconsistent thickness. For example but not limited thereto, in such embodiments, the seal layer 382 may include a top, a bottom and a sidewall coupled to the top and the bottom. A thickness of the top of the seal layer 382 may be greater than a thickness of the bottom of the seal layer 382, and the thickness of the bottom of the seal layer 382 may be greater than a thickness of the sidewall of the seal layer 382. Additionally, the air gaps 382 at two sides of the metal gate structure 350 may include different volumes and/or different shapes.

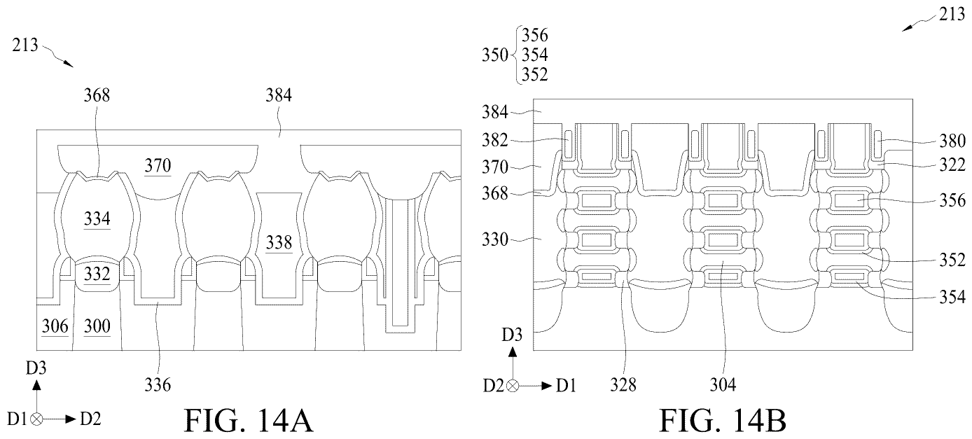

Referring to FIGS. 14A and 14B, in some embodiments, an etch-stop layer 384 is formed over the substrate 300. In some embodiments, the etch-stop layer 384 may include a material different from that of the ILD layer 338. In some embodiments, the etch-stop layer 384 may include SiN, SiCN, SiOCN, or SiOC. In some embodiments, a thickness of the etch-stop layer 384 may be between approximately 2 nanometers and approximately 8 nanometers, but the disclosure is not limited thereto. In some embodiments, the etch-stop layer 384 may be referred to as a middle etch-stop layer (MCESL), but the disclosure is not limited thereto. In some embodiments, the etch-stop layer 384 may cover the contact structure 370.

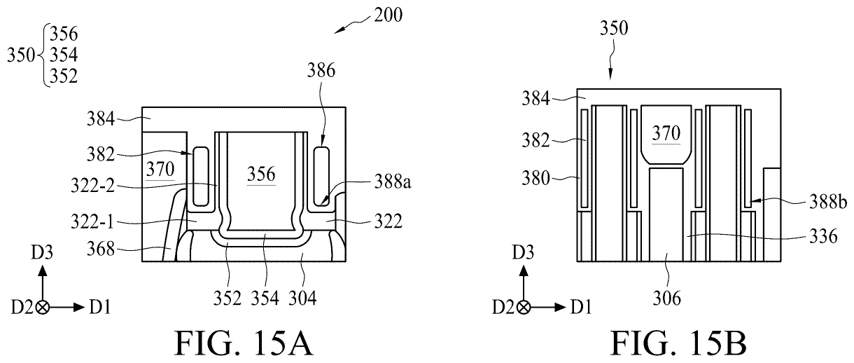

Referring to FIGS. 15A and 15B, which are partially enlarged views of a semiconductor structure 200, in some embodiments, the semiconductor structure 200 may be formed by the method 10 as described above. The semiconductor structure 200 includes a stack of nanostructure channels 304 over a substrate 300, a gate structure (i.e., a metal gate structure) 350 wrapped around each of the nanostructure channels 304, a source/drain structure (i.e., an epitaxial source/drain structure) 330 at two sides of the gate structure 350, a plurality of inner spacers 328 between the gate structure 350, the source/drain structures 330, a sidewall spacer over the gate structure 350, a contact structure 370 electrically connected to the source/drain structure 330, and a metal silicide structure 368 between the source/drain structure 330 and the contact structure 370. In some embodiments, the sidewall spacer includes a dielectric layer 380 (i.e., the seal layer 380) and an air gap 382 sealed within the dielectric layer 380. Materials and dimensions of the nanostructure channels 304, the gate structure 350, the source/drain structure 330, the inner spacers 328 and the dielectric layer 380 may be similar to those described above; therefore such details are not repeated herein.

In some embodiments, a width of the air gap 382 is between approximately 2 nanometers and approximately 8 nanometers. In some embodiments, a top 386 of the air gap 382 is lower than a top surface of the gate structure 350. In some embodiments, the air gap 382 has a first bottom 388a and a second bottom 388b. Further, the first bottom 388a and the second bottom 388b are at different levels. For example, the first bottom 388a is higher than the second bottom 388b. In some embodiments, the first bottom 388a is higher than a bottommost surface of the contact structure 370 (as shown in FIG. 14B), and the second bottom 388b is lower than the bottommost surface of the contact structure 370 (as shown in FIG. 15B). In some embodiments, the second bottom 388b is lower than a bottommost surface of the topmost nanostructure channel 304. In some embodiments, a depth measured from the top of the air gap 386 to the first bottom 388a of the air gap 382 may be between approximately 6 nanometers and approximately 16 nanometers, and a depth measured from the top 386 of the air gap 382 to the second bottom 388b of the air gap 382 may be between approximately 10 nanometers and approximately 50 nanometers, but the disclosure is not limited thereto.

In some embodiments, the sidewall spacer further includes a dielectric layer 322 between the dielectric layer 380 and the gate structure 350. The dielectric layer 322 may include a first portion 322-1 between the dielectric layer 380 and a topmost nanostructure channel 304 of the stack. In such embodiments, the dielectric layer 322 may have a flat configuration. In other embodiments, the dielectric layer 322 further includes a second portion 322-2 between the dielectric layer 380 and the gate structure 350. In such embodiments, the dielectric layer 322 has an L-shaped configuration. In other embodiments, the dielectric layer 322 may include a third portion between the dielectric layer 380 and the contact structure 370, though not shown. In such embodiments, the dielectric layer 322 may have an U-shaped configuration.

In some embodiments, the dielectric layer 322 and the dielectric layer 380 includes different materials. In some embodiments, the dielectric layer 322 and the inner spacer 328 include a same material, but the disclosure is not limited thereto.

Accordingly, the present disclosure provides a semiconductor structure and a method for forming the same. In some embodiments, air gap spacers are formed on sidewalls of a gate structure of a multi-gate transistor device. The air spacers help to reduce the effective capacitance by about 3% to 20%. In some embodiments, uniformity of contact structures, which are formed to provide electrical connection between the multi-gate transistor device and a back-end-of-line (BEOL) interconnect, is improved by the method for forming the semiconductor structure provided by the present disclosure.

According to one embodiment of the present disclosure, a semiconductor structure is provided. The semiconductor structure includes a stack of nanostructure channels, a gate structure wrapping each of the nanostructure channels, a source/drain structure at two sides of the gate structure, and a sidewall spacer over sidewalls of the gate structure. The sidewall spacer includes an air gap sealed within a first dielectric layer.

According to one embodiment of the present disclosure, a semiconductor structure is provided. The semiconductor structure includes a stack of nanostructure channels, a gate structure wrapping each of the nanostructure channels, a source/drain structure at two sides of the gate structure, an air gap disposed at sidewalls of the gate structure, and a contact structure coupled to the source/drain structure. The air gap includes a first bottom and a second bottom. The first bottom is higher than a bottommost surface of the contact structure, and second bottom is lower than the bottommost surface of the contact structure.

According to one embodiment of the present disclosure, a method for forming a semiconductor structure is provided. The method includes following operations. A fin-like stack is formed over a substrate. The fin-like stack includes a plurality of nanostructure channels extending in a first direction. A sacrificial gate structure is formed over the fin-like stack and extends in a second direction. A multi-layered structure is formed over sidewalls of the sacrificial gate structure. The multi-layered structure includes a sacrificial layer. An epitaxial source/drain structure is formed at two sides of the sacrificial gate structure. The sacrificial gate structure is replaced with a metal gate structure. A contact structure is formed to couple to the epitaxial source/drain structure. An air gap is formed in the multi-layered structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a stack of nanostructure channels;
a gate structure wrapping around each of the nanostructure channels;
a source/drain structure at two sides of the gate structure; and
a sidewall spacer over sidewalls of the gate structure, wherein the sidewall spacer comprises an air gap sealed within a first dielectric layer.

2. The semiconductor structure of claim 1, wherein a top of the air gap is lower than a top surface of the gate structure.

3. The semiconductor structure of claim 1, wherein the air gap has a first bottom and a second bottom at different levels.

4. The semiconductor structure of claim 1, further comprising a plurality of inner spacers between the gate structure and the source/drain structures.

5. The semiconductor structure of claim 4, wherein a material of the inner spacers is different from a material of the first dielectric layer.

6. A semiconductor structure comprising:
a stack of nanostructure channels over a substrate;
a gate structure wrapping around each of the nanostructure channels;
a source/drain structure at two sides of the gate structure;
an air gap disposed at sidewalls of the gate structure; and
a contact structure coupled to the source/drain structure,
wherein the air gap comprises a first bottom and a second bottom, the first bottom is higher than a bottommost surface of the contact structure, and the second bottom is lower than the bottommost surface of the contact structure.

7. The semiconductor structure of claim 6, further comprising a first dielectric layer, wherein the air gap is sealed within the first dielectric layer.

8. The semiconductor structure of claim 7, further comprising a second dielectric layer, wherein the second dielectric layer comprises a first portion between the first dielectric layer and a topmost nanostructure channel of the stack.

9. The semiconductor structure of claim 8, wherein the second dielectric layer further comprises a second portion between the first dielectric layer and the gate structure.

10. The semiconductor structure of claim 8, wherein a material of the first dielectric layer is different a material of the second dielectric layer.

11. The semiconductor structure of claim 8, wherein the second dielectric layer has an L configuration.

12. The semiconductor structure of claim 8, further comprising an inner spacer disposed between the gate structure and the source/drain structure.

13. The semiconductor structure of claim 12, wherein the second dielectric layer and the inner spacer comprise a same material.

14. The semiconductor structure of claim 6, further comprising:
a third dielectric layer laterally surrounding the source/drain structure; and
a fourth dielectric layer over the third dielectric layer and covering the contact structure,
wherein the third dielectric layer and the fourth dielectric layer include different materials.

15. A method for forming a semiconductor structure, comprising:
forming a fin-like stack over a substrate, wherein the fin-like stack comprises a plurality of nanostructure channels extending in a first direction;
forming a sacrificial gate structure over the fin-like stack and extending in a second direction;
forming a first dielectric structure over sidewalls of the sacrificial gate structure, wherein the first dielectric structure comprises a sacrificial layer;
forming a source/drain structure at two sides of the sacrificial gate structure;
replacing the sacrificial gate structure with a metal gates structure;
forming a contact structure coupled to the epitaxial source/drain structure; and
forming an air gap in the first dielectric structure.

16. The method of claim 15, further comprising forming a second dielectric structure over the substrate prior to the replacing of the sacrificial gate structure with the metal gate structure.

17. The method of claim 15, further comprising forming a third dielectric structure over the substrate after the replacing of the sacrificial gate structure with the metal gate structure.

18. The method of claim 17, further comprising:
forming an opening in the third dielectric structure, wherein at least a portion of the first dielectric structure is exposed through the opening;
forming a dielectric layer in the opening;
exposing a portion of the source/drain structure through the opening;
forming the contact structure to couple to the portion of the source/drain structure exposed through the opening.

19. The method of claim 15, wherein the forming of the air gap in the first dielectric structure further comprising:
removing the sacrificial layer to form a recess; and
forming a seal layer to seal the recess to form the air gap.

20. The method of claim 19, wherein the first dielectric structure further comprises a dielectric layer, and seal layer and the dielectric layer comprises different materials.
